(19) United States
(12) Patent Application Publication
(10) Pub. No.: US 2026/0293589 A1
(43) Pub. Date: Sep. 24, 2026

(54) SUBSTRATE PROCESSING APPARATUS, SUBSTRATE PROCESSING METHOD, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventors: Katsuji OSHIDA, Toyama-shi (JP); Kaoru YAMAMOTO, Toyama-shi (JP); Toshiro KOSHIMAKI, Toyama-shi (JP)

(73) Assignee: Kokusai Electric Corporation, Tokyo (JP)

(21) Appl. No.: 19/459,004

(22) Filed: Jan. 26, 2026

(30) Foreign Application Priority Data
Mar. 24, 2025 (JP) 2025-047649

(51) Int. Cl. H10P 72/00; G01N 21/25; G01N 21/88; G01N 21/954; H10P 72/10; G01N 21/17

(52) U.S. Cl. CPC H10P 72/0616; G01N 21/255; G01N 21/8851; G01N 21/954; H10P 72/0434; H10P 72/13; G01N 2021/1765; G01N 2021/8887; G01N 2201/06113

(57) ABSTRACT

It is possible to prevent damage to a quartz structure inside a process vessel. There is provided a technique that includes: a process vessel of a tubular shape where substrates supported by a boat are accommodated and collectively processed; a mover for moving the boat in an axial direction of the process vessel; a camera outside the process vessel for imaging inside of the process vessel in a state where one end of the process vessel is open and at least a part of the boat is unloaded from the process vessel; and a determination processor causing the camera to capture an image of the inside of the process vessel in a state where the boat unloaded by the mover is located at the one end of the process vessel, and determining a presence or absence of an abnormality and/or a degree of the abnormality from the image captured.

### CROSS-REFERENCE TO RELATED PATENT APPLICATION

This non-provisional U.S. patent application is based on and claims priority under 35 U.S.C. § 119 of Japanese Patent Application No. 2025-047649, filed on Mar. 24, 2025, in the Japanese Patent Office, the entire contents of which are hereby incorporated by reference.

### BACKGROUND

### 1. Field

The present disclosure relates to a substrate processing apparatus, a substrate processing method, a method of manufacturing a semiconductor device and a non-transitory computer-readable recording medium.

### 2. Related Art

According to some related arts, a tubular structure such as a gas nozzle and a thermocouple may be arranged at a predetermined position inside a vertical type process furnace (which serves as a process vessel) of a substrate processing apparatus. In a manufacturing process of a semiconductor device, the process vessel is configured to accommodate a boat in which wafers serving as semiconductor substrates (also simply referred to as “substrates”) are arranged. The boat is configured such that the wafers can be accommodated therein while arranged vertically in a multistage manner in a horizontal orientation.

When the substrate processing apparatus is repeatedly used to manufacture the semiconductor device, a position of the tubular structure (which is made of quartz and located at the predetermined position inside the process vessel) such as the gas nozzle and the thermocouple may be changed, and a front end (tip) of the tubular structure may tilt toward a center of the process vessel. In such a case, the tubular structure may come into contact with the boat or the semiconductor substrate.

### SUMMARY

According to the present disclosure, there is provided a technique capable of preventing damage to a quartz structure inside a process vessel.

According to an embodiment of the present disclosure, there is provided a technique that includes: a process vessel of a tubular shape in which a plurality of substrates supported by a boat are accommodated and collectively processed; a mover configured to move the boat in a tube axis direction of the process vessel; a camera located outside the process vessel and configured to be capable of imaging an inside of the process vessel in a state where one end of the process vessel is open and a part or an entirety of the boat is unloaded from the process vessel; and a determination processor configured to be capable of causing the camera to capture an image of the inside of the process vessel in a state where the boat unloaded by the mover is located at the one end of the process vessel, and further configured to be capable of determining at least one among a presence or absence of an abnormality and a degree of the abnormality from the image captured by the camera.

### BRIEF DESCRIPTION OF THE DRAWINGS

FIG. 1 is a diagram schematically illustrating a perspective view of a substrate processing apparatus preferably used in one or more embodiments of the present disclosure.

FIG. 2 is a diagram schematically illustrating a vertical cross-section of a process furnace of the substrate processing apparatus preferably used in the embodiments of the present disclosure.

FIG. 3 is a block diagram schematically illustrating a configuration of a controller and its related components of the substrate processing apparatus preferably used in the embodiments of the present disclosure.

FIG. 4A is a flow chart schematically illustrating a flow of a substrate processing preferably used in the embodiments of the present disclosure.

FIG. 4B is a diagram schematically illustrating a temperature change in the substrate processing preferably used in the embodiments of the present disclosure.

FIG. 5 is a diagram schematically illustrating a flow of a machine learning preferably used in the embodiments of the present disclosure.

FIG. 6 is a diagram schematically illustrating an example of an image obtained by a camera preferably used in the embodiments of the present disclosure.

FIG. 7 is a diagram schematically illustrating a method of setting a tilt of a nozzle preferably used in the embodiments of the present disclosure.

FIG. 8 is a diagram schematically illustrating an exemplary configuration of a convolutional neural network (CNN) preferably used in the embodiments of the present disclosure.

FIG. 9 is a diagram schematically illustrating an arrangement of an imaging system according to a first modified example of the present disclosure.

FIG. 10 is a diagram schematically illustrating an arrangement of an imaging system according to a second modified example of the present disclosure.

FIG. 11 is a diagram schematically illustrating an arrangement of an imaging system according to a third modified example of the present disclosure.

### DETAILED DESCRIPTION

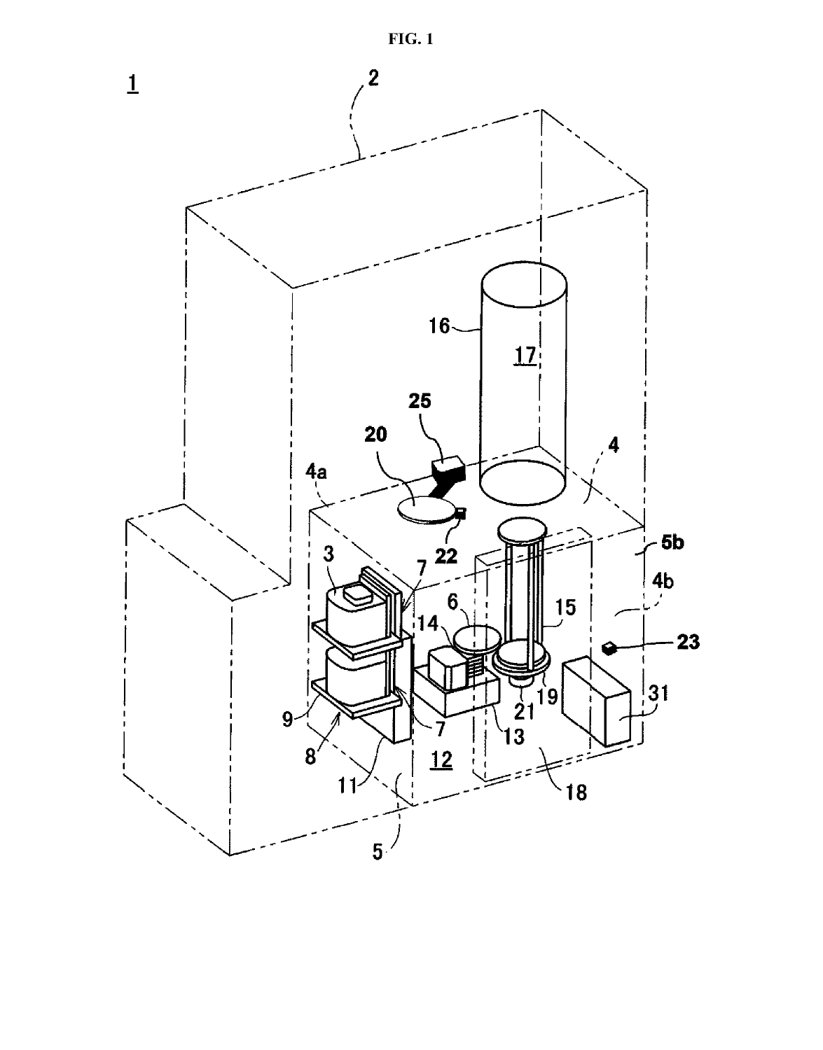

Hereinafter, one or more embodiments (also simply referred to as “embodiments”) of the technique of the present disclosure will be described in detail mainly with reference to FIGS. 1 to 11. The drawings used in the following descriptions are all schematic. For example, a relationship between dimensions of each component and a ratio of each component shown in the drawing may not always match the actual ones. In addition, even between the drawings, the relationship between the dimensions of each component and the ratio of each component may not always match. For example, a substrate processing apparatus 1 according to the present embodiments is configured as a vertical type substrate processing apparatus capable of performing a substrate processing (which is performed as a part of a manufacturing process in a method of manufacturing a semiconductor device) such as a heat treatment process.

### 1. Configuration of Substrate Processing Apparatus

An overall configuration of the substrate processing apparatus 1 will be described with reference to FIG. 1. FIG. 1 is a diagram schematically illustrating main components of the substrate processing apparatus 1.

The substrate processing apparatus 1 includes a housing 2. A pod 3 (which is configured as a sealed type substrate container) may be transferred (loaded) into the substrate processing apparatus 1 by an in-process transfer apparatus (not shown) and may be transferred (unloaded) out of the substrate processing apparatus 1 by the in-process transfer apparatus.

A sub-housing 4 is provided at a lower rear portion of the housing 2 in a front-rear direction to extend toward a rear end of the substrate processing apparatus 1. A pair of wafer loading/unloading ports 7 through which a wafer 6 is loaded into or unloaded out of the sub-housing 4 is provided at a front wall 5 of the sub-housing 4 in two stages in a vertical direction. That is, as the wafer loading/unloading ports 7, an upper wafer loading/unloading port and a lower wafer loading/unloading port are provided. Pod openers 8 are provided for the wafer loading/unloading ports 7, respectively. Hereinafter, each of the wafer loading/unloading ports 7 may also be referred to as a “wafer loading/unloading port 7”, and each of the pod openers 8 may also be referred to as a “pod opener 8”.

The pod opener 8 may include: a mounting table (placement table) 9 where the pod 3 is placed thereon; and an opening/closing structure 11 capable of opening (or detaching) and closing (or attaching) a lid of the pod 3. The pod opener 8 is configured such that a wafer entrance of the pod 3 is opened or closed by opening or closing the lid of the pod 3 placed on the mounting table 9 by using the opening/closing structure 11.

The sub-housing 4 defines a transfer chamber 12 (which is airtight from a space in which the pod opener 8 is located). The transfer chamber 12 may also be referred to as a “loading chamber” or a “loading area”. A substrate transfer structure (hereinafter, also referred to as a “transfer structure” or a “transfer apparatus”) 13 is provided at a front region of the transfer chamber 12. The transfer structure 13 is provided with a predetermined number of wafer mounting plates (which are also referred to as “wafer placement plates” or “wafer grippers”) 14 capable of supporting (or holding) a predetermined number of wafers (for example, five wafers). That is, among a plurality of wafers including the wafer 6, the predetermined number of wafers can be placed on the wafer mounting plates 14. Hereinafter, each of the wafer mounting plates 14 may also be referred to as a “wafer mounting plate 14”, and the plurality of wafers including the wafer 6 may also be referred to as “wafers 6”. The wafer mounting plate 14 is configured to be capable of being moved linearly in a horizontal direction (for example, in an X direction), capable of being rotated in the horizontal direction (for example, in a Y direction) and capable of being elevated or lowered in the vertical direction (for example, in a V direction). The transfer structure 13 is configured such that the wafer 6 can be loaded into or unloaded out of a boat 15 serving as a substrate support provided in the transfer chamber 12. The wafer mounting plates 14 may also be referred to as “hands”, “end effectors”, “chucks”, “forks” or “tweezers”, and may be constituted by, for example, five mounting plates.

A process furnace 16 such as a vertical type process furnace is provided above the transfer chamber 12. The process furnace 16 defines a process chamber (also referred to as a “process vessel”) 17 therein. A lower end of a furnace opening provided adjacent to and below the process chamber 17 is open, and is configured to be opened or closed by using a furnace opening shutter (also referred to as a “shutter”) 20 connected to a shutter driver (which is a shutter driving structure) 25. In the process chamber 17, the heat treatment process is performed on the wafer 6 accommodated in the boat 15. The process vessel 17 is configured as a tubular process vessel capable of accommodating the wafers (substrates) 6 arranged in the boat 15 and capable of processing the wafers (substrates) 6 all at once (or collectively). That is, it is possible to batch-process the wafers 6.

A camera 22 is provided (or mounted) on an edge of the furnace opening shutter 20. Alternatively, two or more cameras may be provided as the camera 22. The camera 22 may also be referred to as a “first camera”, a “first imaging structure” or a “shutter camera”. The camera 22 is installed such that the camera 22 can image an inside (which is an inner portion or an interior) of the process chamber 17, for example, when the boat 15 is transferred from the process furnace 16 to the transfer chamber 12 by a boat elevator 18 described later. The camera 22 can image the inside of the process vessel 17 along a direction upward directly from a center (on a tube axis) of the process vessel 17, for example, during a shutter's movement following its trajectory. The camera 22 is preferably accommodated in a heat resistant case provided with a transmission window. It is also preferable that the camera 22 is locally exhausted (or ventilated) or water-cooled as appropriate. In the present specification, a “local exhaust” refers to a case where an atmosphere (inner atmosphere) of the heat resistant case is sucked and exhausted into the substrate processing apparatus 1 such that the inner atmosphere of the heat resistant case does not leak into the transfer chamber 12.

In addition, a camera (also referred to as a “second camera” or a “second imaging structure”) 23 is provided on an inner wall of a rear wall 5b opposite to the front wall 5 of the sub-housing 4. Similar to the camera 22, the camera 23 is installed such that the camera 23 can image the inside of the process chamber 17, for example, when the boat 15 is transferred from the process furnace 16 to the transfer chamber 12 by the boat elevator 18 described later. Similar to the camera 22, the camera 23 is preferably accommodated in a heat resistant case provided with a transmission window. It is also preferable that the camera 23 is locally exhausted (or ventilated) or water-cooled as appropriate.

The cameras 22 and 23 are installed outside the process vessel 17, and are configured to be capable of imaging (or capturing) the inside of the process vessel 17 when one end (lower end) of the process vessel 17 is open and a part or an entirety of the boat 15 is unloaded from the process vessel 17. Although an exemplary configuration in which the cameras 22 and 23 are installed is shown in FIG. 1, the camera 22 alone may be installed, or the camera 23 alone may be installed. In addition, both of the cameras 22 and 23 may be used to image (or capture) the inside of the process vessel 17, or one of the cameras 22 and 23 alone may be used to image the inside of the process vessel 17.

The boat elevator 18 configured to elevate and lower the boat 15 is provided on a side surface of the sub-housing 4. The boat elevator 18 serves as a mover (which is a moving structure) configured to move the boat 15 in a tube axis direction (that is, a direction along the tube axis) of the process vessel 17. The tube axis direction may also be referred to as an “axial direction”. A seal cap 19 serving as a lid is attached horizontally to an arm (not shown) connected to an elevating platform of the boat elevator 18. The seal cap 19 is configured to support the boat 15 vertically, and is configured to be capable of airtightly closing the furnace opening after the boat 15 is loaded into the process furnace 16. The transfer chamber 12 is provided adjacent to the process chamber 17. The boat 15 is accommodated in the transfer chamber 12 or the process chamber 17. In the transfer chamber 12, the wafer 6 is loaded into or unloaded out of the boat 15. The boat 15 is configured to support (or hold) the plurality of wafers 6 (for example, from 50 wafers to 175 wafers) while the wafers 6 are horizontally oriented with their centers aligned with one another in a multistage manner.

A rotator (which is a rotating structure) 21 is provided at the seal cap 19 to be opposite to the process chamber 17. The rotator 21 is configured to support (that is, rotatably support) the boat 15 such that the boat 15 can be rotated around a central axis corresponding to the center of the wafer 6. A rotating shaft 28 of the rotator 21 passes through the seal cap 19, and is connected to the boat 15. The rotator 21 serves as a rotation driver (which is a rotation driving structure) configured to rotate the boat 15. That is, the rotator 21 is configured to rotate the wafers 6 by rotating the boat 15 within the process chamber 17.

A clean air supplier (which is a clean air supply structure) (not shown) is disposed at a location adjacent to a first side surface 4a of the sub-housing 4 to be opposite to the boat elevator 18 (that is, opposite to a second side surface 4b of the sub-housing 4). For example, the clean air supplier is constituted by a supply fan and a dust filter to supply clean air (which is purified air or an inert gas). On the first side surface 4a of the sub-housing 4 (that is, a first side surface of the transfer chamber 12), an outlet for the clean air is provided. A notch aligner (which is a notch alignment structure) (not shown) may be installed between the transfer structure 13 and the clean air supplier. The notch aligner serves as a substrate aligner (which is a substrate alignment structure) configured to align a circumferential position of the wafer 6.

The clean air is ejected through the clean air supplier. Then, after circulating through the notch aligner, the transfer structure 13 and the boat 15, a part of the clean air is sucked in by a local exhaust duct (or a common exhaust duct) installed on a second side surface of the transfer chamber 12 and exhausted to an outside (outer portion) of the housing 2 through an exhaust duct. The second side surface 4b of the sub-housing 4 (that is, the second side surface of the transfer chamber 12) is provided with an exhaust port. Another part of the clean air is ejected again into the transfer chamber 12 through the clean air supplier.

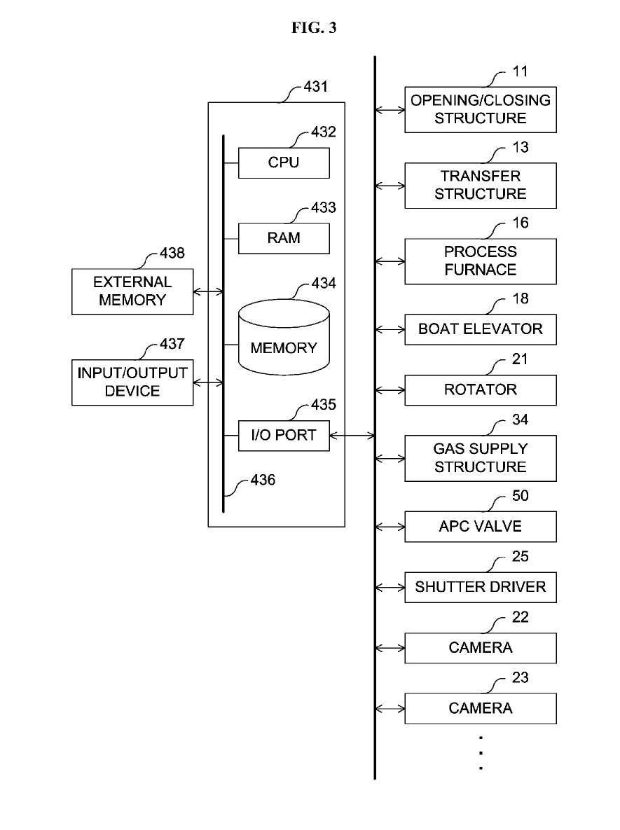

For example, a controller box 31 is provided with a controller 431 serving as a control structure to be described with reference to FIG. 3.

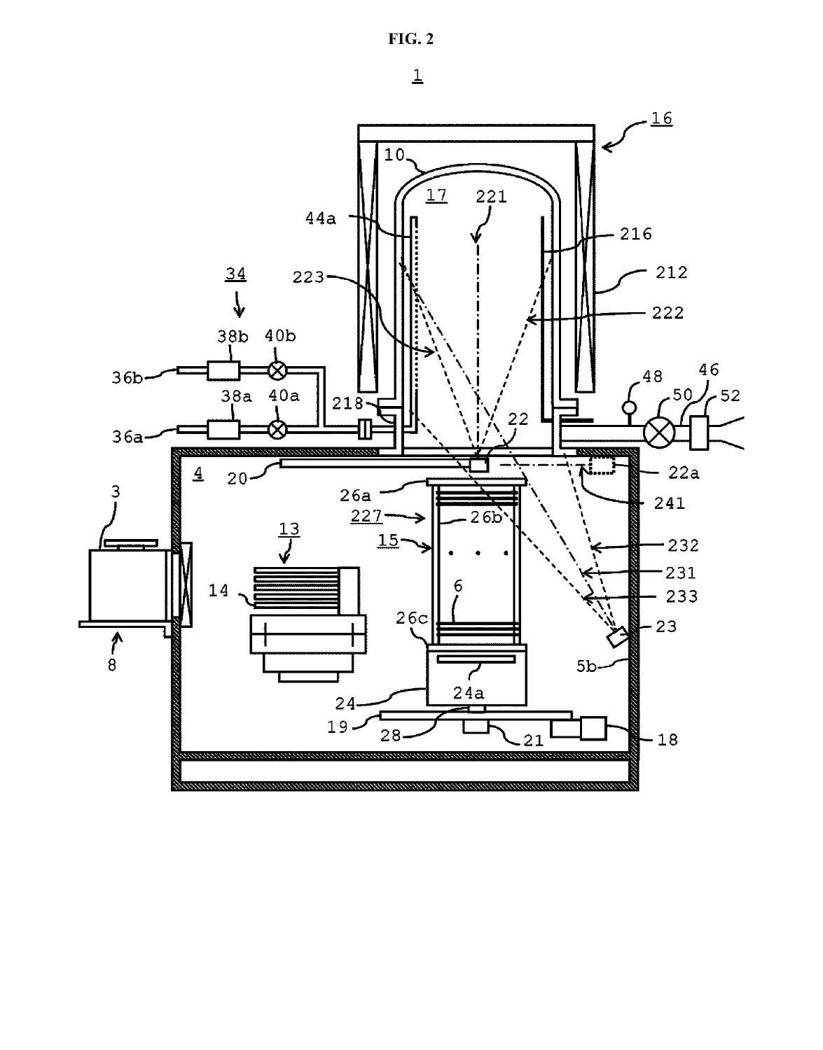

As shown in FIG. 2, the process furnace 16 includes a reaction tube 10 of a cylindrical shape and a heater 212 serving as a first heating structure (first heater) installed an outer periphery of the reaction tube 10. For example, the reaction tube 10 is made of a material such as transparent quartz and silicon carbide (SiC). The process chamber 17 is defined by an inside (which is an inner portion or an interior) of the reaction tube 10. The wafer 6 serving as the substrate is processed in the process chamber 17. A temperature detector 216 serving as a temperature detection structure is installed in the reaction tube 10. The temperature detector 216 is installed upright in an up-down direction (vertical direction) along an inner wall of the reaction tube 10. In addition, a nozzle (also referred to as a “gas nozzle”) 44a described later through which a gas is supplied is installed in the up-down direction along the inner wall of the reaction tube 10. In other words, the gas nozzle 44a is located at a predetermined position inside the process vessel 17.

A manifold 218 of a cylindrical shape is connected to a lower end opening of the reaction tube 10 via a seal such as an O-ring, and is configured to support a lower end of the reaction tube 10. For example, the manifold 218 is made of a metal material such as stainless steel. A lower end opening of the manifold 218 is opened and closed by the shutter 20 of a disk shape or the lid 19 (that is, the seal cap 19). For example, the lid 19 is made of a metal material, and is of a disk shape. Seals such as O-rings are installed on an upper surface of the shutter 20 and an upper surface of the lid 19, respectively. Thereby, it is possible to airtightly seal the inside of the reaction tube 10 from the outside air.

As described above, the camera 22 is provided on the edge of the shutter 20, and the camera 23 is provided on the inner wall of the rear wall 5b opposite to the front wall 5 of the sub-housing 4. In FIG. 2, the shutter 20 in a half-open state is shown, and an optical axis (indicated by a dash-dotted line 221) of the camera 22, angles of view (indicated by dashed lines 222 and 223) of the camera 22, an optical axis (indicated by a dash-dotted line 231) of the camera 23 and angles of view (indicated by dashed lines 232 and 233) of the camera 23 are also shown. In an example shown in FIG. 2, the optical axis 221 of the camera 22 is directed upward so as to be set at approximately (or substantially) a central portion of the reaction tube 10 in a left-right direction, and the camera 22 is configured such that the nozzle 44a and the temperature detector 216 installed inside the reaction tube 10 are located within a range defined by the angles of view 222 and 223 of the camera 22. In the example shown in FIG. 2, the optical axis 231 of the camera 23 is directed from a lower right end portion of the reaction tube 10 toward a front end (tip) of the nozzle 44a installed inside the reaction tube 10, and the camera 23 is configured such that the nozzle 44a is located within a range defined by the angles of view 232 and 233 of the camera 23. As a result, the camera 22 is configured to be capable of imaging (or obtaining) a state of the nozzle 44a of the reaction tube 10 and the temperature detector 216, and the camera 23 is configured to be capable of imaging the state of the nozzle 44a of the reaction tube 10.

In addition, when the boat 15 accommodates the wafers (substrates) 6 processed in the process vessel 17 and unloaded from the process vessel 17, the cameras 22 and 23 are configured to be capable of imaging the inside of the process vessel 17 and a tubular structure (such as the nozzle 44a and the temperature detector 216) through a gap between the boat 15 and an opening at one end (lower end) of the process vessel 17 (that is, the lower end of the furnace opening in the vicinity of a lower portion of the process vessel 17) while the heater 212 configured to heat the process vessel 17 is maintained in a powered state (that is, turned on).

A heat insulator (which is a heat insulating structure) 24 is placed on the lid 19. For example, the heat insulator 24 is made of quartz. The heat insulator 24 is provided with a cap heater 24a serving as a second heating structure (second heater) on a surface thereof or inside thereof. The cap heater 24a is configured to heat the wafer (substrate) 6 located at the lower portion of the process chamber 17 or accommodated in a lower portion of the boat 15. The boat 15 serving as the substrate support is installed above the heat insulator 24. For example, the boat 15 is constituted by a top plate 26a, a bottom plate 26c, and a plurality of columns 26b serving as substrate support columns installed between the top plate 26a and the bottom plate 26c. The boat 15 is configured to support the wafers 6 (for example, from 25 wafers to 150 wafers) vertically arranged in a multistage manner by placing the wafers 6 in a plurality of grooves formed at the columns 26b in a multistage manner. For example, the boat 15 is made of a material such as quartz and SiC. A substrate retainer 227 is constituted by the heat insulator 24 and the boat 15. During the substrate processing, the substrate retainer 227 is accommodated in the process chamber 17. In other words, on a side (portion) closest to the process vessel 17 when the boat 15 is unloaded from the process vessel 17, the boat 15 includes the top plate 26a provided with a transparent portion or an opening and located approximately (or substantially) perpendicular to the tube axis of the process vessel 17 and to which the plurality of columns 26b serving as the substrate support columns are connected. The cameras 22 and 23 are located such that the cameras 22 and 23 can image the nozzle 44a through the transparent portion or the opening provided in the top plate 26a.

The heat insulator 24 is connected to the rotating shaft 28 passing through (or penetrating) the lid 19. The rotating shaft 28 is connected to the rotator 21 provided below the lid 19. By rotating the rotating shaft 28 using the rotator 21, the heat insulator 24 and the boat 15 can be rotated.

The substrate transfer structure 13, the boat 15 and the boat elevator 18 serving as an elevating structure are provided within the transfer chamber 12. The substrate transfer structure 13 is provided with the wafer mounting plates 14 capable of picking up, for example, five wafers among the wafers 6. The substrate transfer structure 13 is configured to be capable of transferring the wafer 6 between the boat 15 and the pod 3 placed at a position of the pod opener 8 by rotating the wafer mounting plate 14 up and down using a driver (which is a driving structure). The boat elevator 18 is configured to load or unload the boat 15 into or from the reaction tube 10 by elevating or lowering the lid 19 in the vertical direction.

The substrate processing apparatus 1 is provided with a gas supply structure 34 configured to supply gases (which are used for the substrate processing) into the process chamber 17. The gases supplied by the gas supply structure 34 may be changed as appropriate in accordance with a type of a film to be formed. The gas supply structure 34 may include a source gas supplier (which is a source gas supply system), a reactive gas supplier (which is a reactive gas supply system) and an inert gas supplier (which is an inert gas supply system).

The source gas supply system includes a gas supply pipe 36a. A mass flow controller (MFC) 38a serving as a flow rate controller (flow rate control structure) and a valve 40a serving as an opening/closing valve are sequentially installed at the gas supply pipe 36a in this order from an upstream side to a downstream side of the gas supply pipe 36a in a gas flow direction. The gas supply pipe 36a is connected to the nozzle 44a which penetrates a side wall of the manifold 218. The nozzle 44a is installed upright in the reaction tube 10 in the up-down direction, and is provided with a plurality of supply holes which open toward the wafers 6 accommodated in the boat 15. A source gas is supplied to the wafers 6 through the supply holes of the nozzle 44a.

Similarly, a reactive gas is supplied to the wafers 6 from the reactive gas supply system through the gas supply pipe 36a, the MFC 38a, the valve 40a and the nozzle 44a. Similarly, an inert gas is supplied to the wafers 6 from the inert gas supply system through a gas supply pipe 36b, an MFC 38b, a valve 40b and the nozzle 44a. In FIG. 2, an example in which the nozzle 44a alone is provided is shown. However, a plurality of nozzles may be provided inside the process chamber 17. For example, instead of the nozzle 44a, a nozzle for the source gas supply system, a nozzle for the reactive gas supply system and a nozzle for the inert gas supply system may be provided.

An exhaust pipe 46 is provided at the manifold 218. A vacuum pump 52 serving as a vacuum exhaust apparatus is connected to the exhaust pipe 46 via a pressure sensor 48 serving as a pressure detector (pressure detection structure) configured to detect a pressure (inner pressure) of the process chamber 17 and an APC (Automatic Pressure Controller) valve 50 serving as a pressure regulator (which is a pressure adjusting structure). With such a configuration, it is possible to set the inner pressure of the process chamber 17 to a process pressure in accordance with a processing.

In FIG. 2, an example in which the camera 22 is provided on the edge of the shutter 20 is shown. However, the present embodiments are not limited thereto. For example, when a camera 22a is provided on a ceiling wall of the transfer chamber 12, (that is, on a ceiling wall of the sub-housing 4) in an edge area of the furnace opening in the vicinity of the lower portion of the process vessel 17, as shown by a dotted box in FIG. 2, and when an optical axis 241 of the camera 22a is parallel to the ceiling wall of the sub-housing 4, an optical axis converter (which is an optical axis conversion structure) such as a mirror and a prism configured to convert the optical axis 241 toward the tube axis direction of the process vessel 17 may be provided on the edge of the shutter 20 instead of the camera 22. For example, the optical axis 241 is converted to the optical axis 221 by the optical axis converter. For example, a plurality of mirrors or a plurality of prisms may also be provided on the edge of the shutter 20. In other words, one or more mirrors (or one or more prisms) are provided in locations where a target location of image capture of the nozzle 44a is visible through the gap between the opening of the process vessel 17 and the boat 15 when unloaded from the process vessel 17 such that a light from the target location of image capture can be directed to the camera 22a.

In other words, the shutter 20 is provided, on the edge thereof, with the camera 22 or a set of the camera 22a and the optical axis converter (that is, one or more mirrors or one or more prisms). The camera 22 or the camera 22a is configured to be capable of imaging the inside of the process vessel 17 during an opening and closing operation of the shutter 20.

Even in such a configuration, it is possible to image the inside of the process vessel 17 using the camera 22a and the optical axis converter (that is, one or more mirrors or one or more prisms) attached to the edge of the shutter 20.

In addition, the controller box 31 accommodating the controller 431 serving as the control structure (which is a control apparatus or a control system) is provided at an appropriate position in the housing 2, for example, in a corner of the sub-housing 4 in FIG. 1. As shown in FIG. 3, the controller 31 is constituted by a computer including a CPU (Central Processing Unit) 432, a RAM (Random Access Memory) 433, a memory 434 and an I/O port (input/output port) 435. The RAM 433, the memory 434 and the I/O port 435 are configured to be capable of exchanging data with the CPU 432 through an internal bus 436. For example, an input/output device 437 (which is constituted by components such as a touch panel) is connected to the controller 431. In addition, an external memory 438 may also be connected to the controller 431. The controller 431 is configured to be capable of performing (or executing) an artificial intelligence (AI) program.

The controller 431 serving as a determination processor (determination structure) is configured to cause the cameras 22 and 23 to capture images of the inside of the process vessel 17 while the boat 15 unloaded from the process vessel 17 by the boat elevator 18 serving as the mover is at one end (lower end) of the process vessel 17, and further configured to determine, from the images captured (or obtained) by the cameras 22 and 23, one or more among a presence or absence of an abnormality inside the process vessel 17 and a degree (severity) of the abnormality. In other words, the controller 431 determines a presence or absence or a degree of an abnormality in a distance between an inner wall of the process vessel 17 and the gas nozzle 44a, or in a parallelism between the tube axis of the process vessel 17 and the gas nozzle 44a.

In the present specification, a state in which “the boat 15 is at one end (lower end) of the process vessel 17” refers to a state in which the boat 15 has been unloaded from the process vessel 17 by moving the boat 15 only in the tube axis direction of the process vessel 17, that is, a state in which the boat 15 is located directly below the furnace opening (which is provided adjacent to and below the process vessel 17), and is not moved horizontally using a component such as a boat changer after unloaded from the process vessel 17. For example, even when the boat 15 is not completely unloaded from the process vessel 17, that is, even when an upper end of the boat 15 does not fully protrude from the furnace opening of the process vessel 17, it is possible to image the inside of the process vessel 17 with the cameras 22 and 23. In addition, “a presence or absence or a degree of an abnormality” is not limited to a degree of an abnormality at a time of imaging, and may also include a degree of temporal or probabilistic scale that can predict a future abnormality.

For example, the memory 434 is configured by a component such as a flash memory, a hard disk drive (HDD) and a solid state drive (SSD). For example, a control program configured to control an operation of the substrate processing apparatus 1 and a process recipe containing information on procedures and conditions of the substrate processing described later may be readably stored in the memory 434. The process recipe is obtained by combining steps (procedures) of the substrate processing described later such that the controller 431 can execute the steps by the substrate processing apparatus 1 to acquire a predetermined result, and functions as a program. Hereinafter, the process recipe and the control program may be collectively or individually referred to as a “program”. In addition, the process recipe may also be simply referred to as a “recipe”. Thus, in the present specification, the term “program” may refer to the recipe alone, may refer to the control program alone or may refer to both of the recipe and the control program. The RAM 433 functions as a memory area (work area) where a program or data read by the CPU 432 is temporarily stored.

The I/O port 435 is connected to the components described above such as the opening/closing structure 11, the transfer structure 13, the process furnace 16, the boat elevator 18, the rotator 21, the gas supply structure 34 (the MFCs 38a and 38b and the valves 40a and 40b), the APC valve 50, the shutter driver 25 and the cameras 22 and 23.

The CPU 432 is configured to read the control program from the memory 434 and execute the control program read from the memory 434. In addition, the CPU 432 is configured to read the recipe from the memory 434, for example, in accordance with an operation command inputted from the input/output device 437. In accordance with contents of the recipe read from the memory 434, the CPU 432 may be configured to be capable of controlling various operations such as an operation of opening and closing the lid of the pod 3, an operation of transferring the wafer 6 by the transfer structure 13, an operation of supplying a process gas into the process furnace 16 and exhausting the process gas from the process furnace 16, an operation of adjusting a flow rate of the process gas, an operation of controlling the inner pressure of the process chamber 17, an operation of adjusting a temperature (inner temperature) of the process chamber 17, an operation of elevating and lowering the boat 15 by the boat elevator 18, and an operation of adjusting a rotation and a rotation speed of the boat 15 by the rotator 21. In addition, the CPU 432 may be configured to be capable of controlling various operations such as the opening and closing operation of the shutter 20 by the shutter driver 25, a control of an imaging operation of the cameras 22 and 23, an operation of obtaining the images captured by the cameras 22 and 23 and an operation of analyzing the images. It is preferable that the images are analyzed by the artificial intelligence (AI) program executed by the CPU 432, for example. For example, the images may be analyzed by an artificial intelligence (AI) program executed by a processing apparatus such as a CPU provided in another computer (such as a server apparatus and a management apparatus) connected to the substrate processing apparatus 1 via a network.

The controller 431 may be embodied by installing the above-described program stored in the external memory 438 into the computer. For example, the external memory 438 may include a magnetic disk such as a hard disk drive (HDD), an optical disk such as a CD, a magneto-optical disk such as an MO and a semiconductor memory such as a USB memory and a solid state drive (SSD). The memory 434 or the external memory 438 may be embodied by a non-transitory computer readable recording medium. Hereafter, the memory 434 and the external memory 438 may be collectively or individually referred to as a “recording medium”. Thus, in the present specification, the term “recording medium” may refer to the memory 434 alone, may refer to the external memory 438 alone, or may refer to both of the memory 434 and the external memory 438. Instead of the external memory 438, a communication interface such as the Internet and a dedicated line may be used for providing the program to the computer.

### 2. Substrate Processing

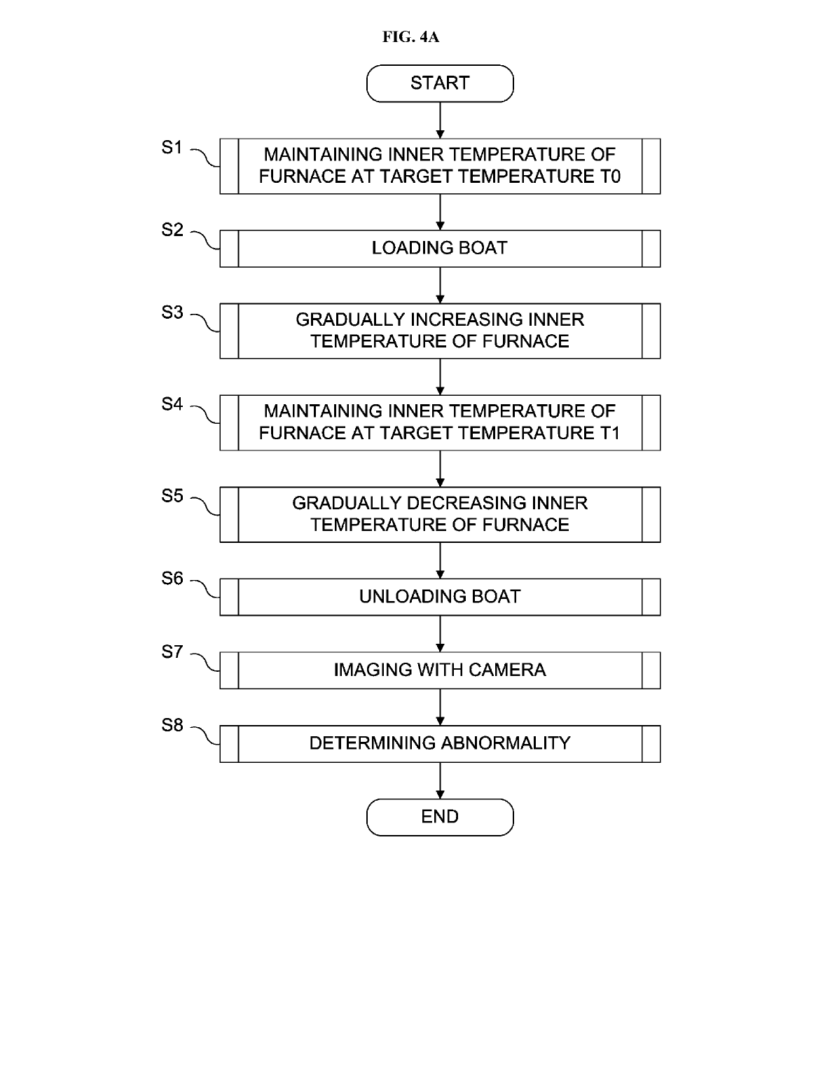

In the substrate processing apparatus 1 provided with the process vessel 17 shown in FIG. 2, for example, a processing step shown in FIG. 4A is performed. FIG. 4A is a flow chart schematically illustrating an example of the processing step (that is, the substrate processing) performed by the substrate processing apparatus 1, and FIG. 4B is a diagram schematically illustrating a temperature change in a temperature (inner temperature) of a furnace during the processing step.

### Step S1

A step S1 is a process (step) of stabilizing the inner temperature of the furnace (that is, the process vessel 17) at a relatively low temperature (that is, a target temperature T0). In the step S1, the boat 15 has not yet been inserted into the furnace.

### Step S2

A step S2 is a process (step) of inserting (loading) the boat 15 into the furnace (boat loading step). In such an operation, a temperature of the wafer 6 is usually lower than the target temperature T0. Therefore, when the boat 15 is loaded into the furnace, the inner temperature of the furnace temporarily falls below the target temperature T0. To quickly recover from such temperature decrease and to stabilize the inner temperature of the furnace within a small temperature range around the target temperature T0, a temperature controller adjusts an amount of operation (also referred to as an “operation amount”) of the heater 212.

### Step S3

A step S3 is a process (ramp-up step) of gradually increasing the inner temperature of the furnace from the target temperature T0 to a target temperature T1 for performing a process such as a film forming process on the wafer 6. When ramping up, the inner temperature of the furnace is increased slower than a target gradient. Thus, it takes some time to stabilize the inner temperature of the furnace within a small temperature range around the target temperature T1.

### Step S4

A step S4 is a process (step) of stabilizing the inner temperature of the furnace at the target temperature T1 in order to perform the process such as the film forming process on the wafer 6.

### Step S5

A step S5 is a process (step) of gradually decreasing the inner temperature of the furnace from the target temperature T1 back to the relatively low temperature (that is, the target temperature T0).

### Step S6

A step S6 is a process (step) of transferring (unloading) the boat 15 accommodating the processed wafer 6 out of the furnace.

### Step S7

A step S7 is a process (step) of imaging the inside of the process vessel 17 using the camera 22 or the camera 23. In the step S7, after the boat 15 is unloaded from the furnace, the inside of the process vessel 17 is imaged using the camera 22 or the camera 23. Image data on the inside of the process vessel 17 is sent to the controller 431 serving as the determination processor. In the step S7 (a step of imaging with the camera), it is possible to image the inside of the process vessel 17 by utilizing the light emitted by the heater 212 without additional lighting. For example, when there is insufficient light, it is preferable to install an appropriate lighting apparatus.

### Step S8

A step S8 is a process (step) of analyzing the image data using the controller 431 and determining whether or not an abnormality exists inside the process vessel 17. The step S8 (a step of determining the abnormality) is performed by estimating a tilt (inclination) of the nozzle 44a in a radial direction of the reaction tube 10 (that is, a radial tilt of the nozzle 44a). In the present specification, the term “tilt of the nozzle 44a” may include a tilt of the nozzle 44a approaching a tube axis of the reaction tube 10 or a tilt of the nozzle 44a toward the inner wall of the reaction tube 10. In the present embodiments, estimating the tilt of the nozzle 44a is described. However, in the step S8, a tilt (inclination) of the temperature detector 216 may be estimated, or both of the tilt of the nozzle 44a and the tilt of the temperature detector 216 may be estimated. Each of the nozzle 44a and the temperature detector 216 may also be referred to as the “tubular structure” arranged at a predetermined position inside the process vessel 17.

The steps S7 and S8 may also be rephrased as the following steps.
(a) a step of accommodating the plurality of wafers (substrates) 6 supported by the boat 15 into the process vessel 17 of a cylindrical shape (tubular shape) and collectively processing (or batch-processing) the plurality of wafers (substrates) 6 supported by the boat 15;
(b) a step of moving the boat 15 in the tube axis direction (axial direction) of the process vessel 17 by the mover (that is, the boat elevator 18) after (a) and unloading the boat 15 from the process vessel 17;
(c) a step of imaging the inside of the process vessel 17 by using the camera 22, 23 or 22a located outside the process vessel 17, in a state where one end (lower end) of the process vessel 17 is open; and
(d) a step of determining the presence or absence or the degree of the abnormality from the images captured by using the camera 22, 23 or 22a.

Since the steps S1 to S8 are usually performed repeatedly, it is possible to improve the productivity by performing each step in a short time. In particular, as one of performance requirements for a temperature control, a reduction in a time (settling time) for the temperature to be stabilized within a small temperature range relative to the target temperature during the boat loading step and the ramp-up step is considered.

In addition, by providing the step S7 (the step of imaging with the camera) and the step S8 (the step of determining the abnormality), it is possible to determine the tilt of the nozzle 44a and/or the tilt of the temperature detector 216, and it is also possible to reduce a downtime of the substrate processing apparatus 1 by preventing the damage to a quartz structure (that is, a structure made of quartz) due to a contact between the nozzle 44a (or the temperature detector 216) and the boat 15.

In the present specification, the term “wafer” may refer to “a wafer itself”, or may refer to “a wafer and a stacked structure (aggregated structure) of a predetermined layer (or layers) or a film (or films) formed on a surface of the wafer”. In the present specification, the term “a surface of a wafer” may refer to “a surface of a wafer itself”, or may refer to “a surface of a predetermined layer (or a predetermined film) formed on a wafer”. Thus, in the present specification, “forming a predetermined layer (or a film) on a wafer” may refer to “forming a predetermined layer (or a film) directly on a surface of a wafer itself”, or may refer to “forming a predetermined layer (or a film) on another layer (or another film) formed on a wafer”. In the present specification, the terms “substrate” and “wafer” may be used as substantially the same meaning.

### 3. Flow of Machine Learning

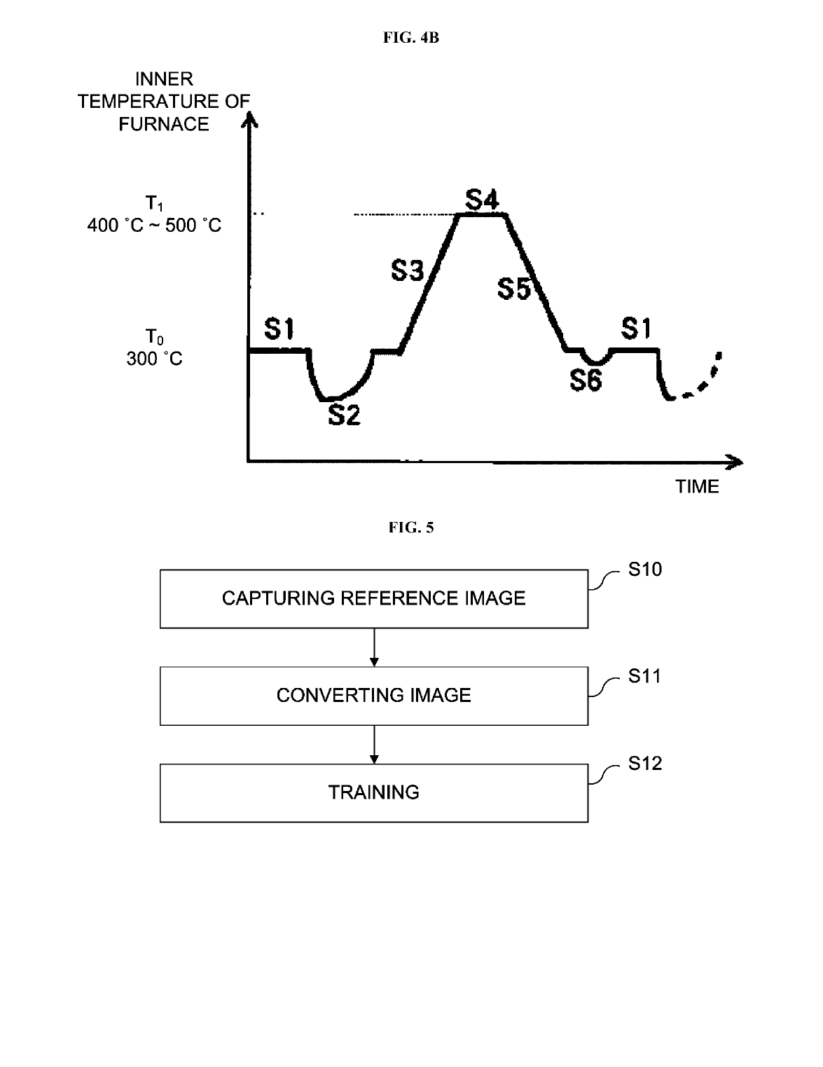

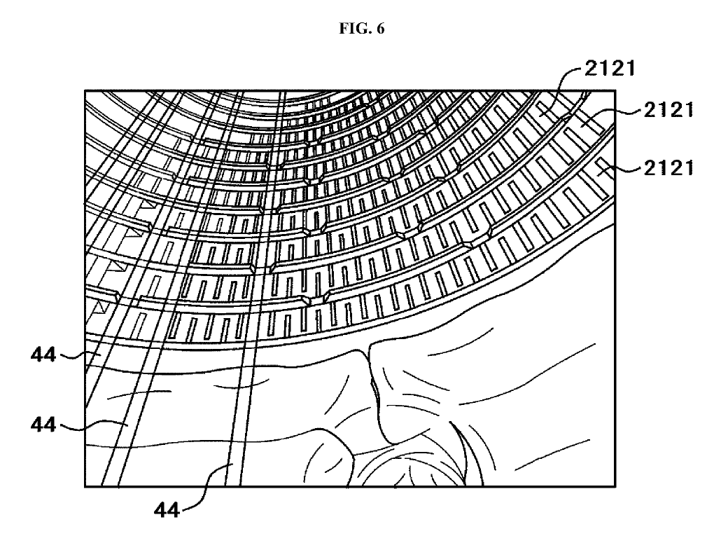

Subsequently, a flow of a machine learning will be described with reference to FIG. 5. FIG. 6 is a diagram schematically illustrating an example of an image obtained (or captured) by a camera.

### Step S10: Capturing Reference Image

In the following description, the term “master apparatus” refers to another substrate processing apparatus provided with a process vessel and a camera (or cameras) in substantially the same layout as the substrate processing apparatus 1 provided with the process vessel 17 and the cameras 22 and 23 described with reference to FIGS. 1 and 2.

While changing the radial tilt of the nozzle 44a or a tangential tilt of the nozzle 44a (that is, the tilt of the nozzle 44a in a tangential direction), the camera of the master apparatus captures a plurality of images (see FIG. 6) as reference images. It is preferable to capture the images under a plurality of states with different levels of contamination of the process vessel and the nozzle. In addition, a plurality of images may be prepared as the reference images by changing an angle of view (such as a position or a viewpoint, a shooting direction, a magnification), a focusing state and lighting conditions of the camera. For example, the images used to create a machine learning model may be the images of the substrate processing apparatus 1 itself (which is a subject of capturing and evaluating) may be the images of an apparatus (that is, the master apparatus) different from the substrate processing apparatus 1 which is the subject of capturing and evaluating. For example, the images under the plurality of states with different levels of contamination of the process vessel and the nozzle are preferably acquired by the cameras 22 and 23 of the substrate processing apparatus 1.

FIG. 6 is a diagram schematically illustrating the example of the image captured by the camera. For example, the image shows a plurality of gas nozzles 44 (which are made of quartz) and installed inside the reaction tube 10 (which is made of quartz) of the process vessel 17, with the heater 212 visible through the reaction tube 10 made of quartz. An inner wall of the heater 212 is configured as a heater coil 2121 surrounding the reaction tube 10 of a tubular shape. The heater coil 2121 is configured as a structure in which circular rings are arranged in a multistage manner.

### Step S11: Converting Image

The reference images captured in the step S10 are converted into images suitable for a training process (learning process). For example, each of the reference images is converted into a grayscale image or an HSV image. The “HSV image” is an image configured to express a color using a combination of hue, saturation and value. For example, it is also preferable to mask portions of the image that are unrelated to the tilt of the nozzle 44a.

It is also preferable to increase the number of the images by performing a spatial filtering such as a sharpening (unsharp masking), a correction such as a tone curve correction and a transformation such as a translation and a rotation under various conditions. Alternatively, a plurality of images of the same nozzle 44a captured (or taken) at different angles of view may be combined. For example, a stereo image may be generated in which images of the nozzle 44a taken from diagonally downward left and diagonally downward right are arranged side by side. The image such as the stereo image is labeled with a degree of the radial tilt of the nozzle 44a or labeled with whether it is normal or abnormal.

### Step S12: Training

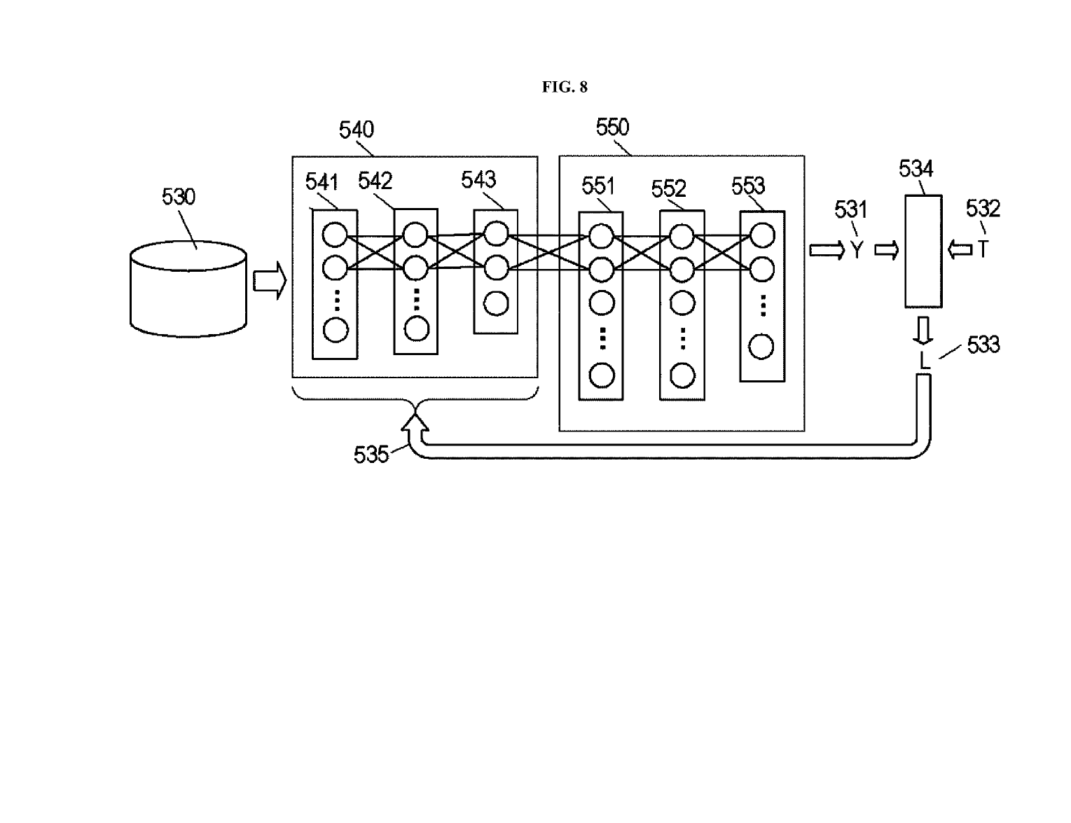

An artificial intelligence (such as a convolutional neural network) is trained using the images prepared in the step S11. In other words, a relationship between image information and label information is trained (or learned) through a machine learning to generate the machine learning model. The training is performed by updating parameters of the convolutional neural network (CNN) using an error backpropagation method (whose details are described in FIG. 8 below).

According to the present embodiments, for example, the label information may be freely (appropriately) set as a label for a degree of contamination of the process vessel (large, medium, small, etc.), a label for a degree of contamination of the nozzle (large, medium, small, etc.), a label for the tilt of the nozzle (large, medium, small, etc.), a label for the tilt of the temperature detector (large, medium, small, etc.), a degree of deterioration of the boat (large, medium, small, etc.) and a degree of damage to the substrate (large, medium, small, etc.).

The controller 431 serving as the determination processor configured to determine the presence or absence and/or the degree of the abnormality, based on the machine learning model created in advance using the images captured by the camera of the substrate processing apparatus (in the present embodiments, the master apparatus) provided with the process vessel and the camera (or the cameras) in substantially the same layout as the process vessel 17 and the cameras 22 and 23 when the substrate processing apparatus is normal, or created in advance using the images of the process vessel and the nozzle under the plurality of states with different levels of contamination. As a result, it is possible to determine and estimate a state of the quartz structure inside the process vessel. Thereby, it is possible to prevent the damage to the quartz structure. In addition, it is also possible to determine and estimate the level of contamination of the process vessel and the nozzle. Thereby, it is possible to determine whether or not to perform a cleaning operation for the process vessel and the nozzle.

### Method of Setting Tilt of Nozzle

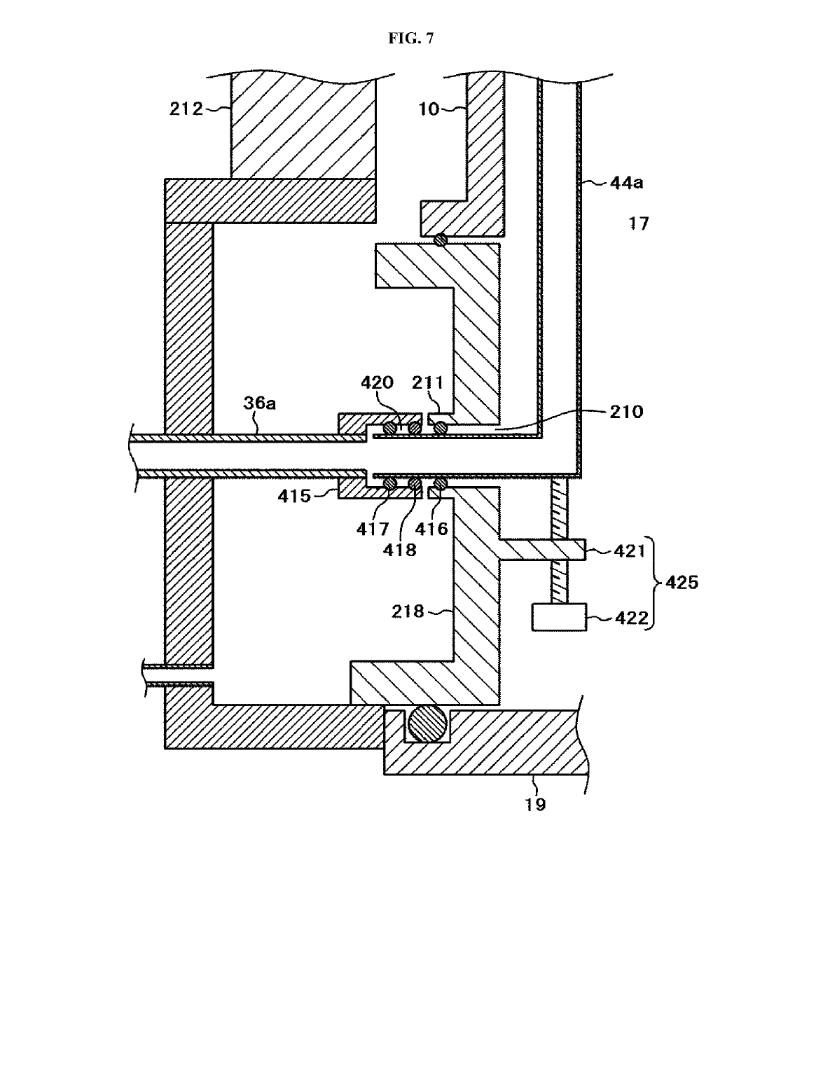

Subsequently, a method of setting the tilt of the nozzle will be described with reference to FIG. 7.

An upstream side (base) of the nozzle 44a connected to the gas supply pipe 36a is of an L shape, and a horizontal portion of the nozzle 44a horizontally penetrates the side wall of the manifold 218. An O-ring 416 is provided between the horizontal portion of the nozzle 44a and the side wall of the manifold 218 to ensure the airtightness in the process chamber 17. For example, according to the present embodiments, a nozzle port 210 of a tubular shape extending radially from the side wall of the manifold 218 is provided. An inner diameter of the nozzle port 210 is slightly greater than an outer diameter of the horizontal portion of the nozzle 44a. The gas supply pipe 36a is inserted into the nozzle port 210 while the O-ring 416 is provided between the gas supply pipe 36a and the nozzle 44a.

The upstream side of the nozzle 44a protrudes outward from the side wall of the manifold 218, and is airtightly coupled to a joint 415 provided at a downstream end of the gas supply pipe 36a. A downstream end of the nozzle 44ais bent vertically upward in the reaction tube 10. O-rings 417 and 418 are provided between the downstream end of the gas supply pipe 36a and the joint 415.

Since the nozzle 44a is heated by the heater 212, the nozzle 44a is made of a heat resistant material (for example, a non-metallic material such as quartz and silicon carbide). In addition, the upstream side (that is, the base) of the nozzle 44a may be made of a metal such as a nickel alloy.

In addition, a nozzle tilt adjusting structure (also referred to as a “nozzle support”) is provided below a bent portion of the nozzle 44a. The nozzle tilt adjusting structure may include: a pedestal (also referred to as a “bracket”) 421 provided on an inner wall of the manifold 218; and a tilt adjusting screw 422 that vertically penetrates a screw hole provided in the pedestal 421. By adjusting a height of the tilt adjusting screw 422 and bringing an upper end of the tilt adjusting screw 422 into contact with the bent portion of the nozzle 44a from thereunder, it is possible to adjust the tilt of the nozzle 44a or distances between gas supply holes of the nozzle 44a and the wafers 6.

In a manner described above, it is possible to adjust (or change) the radial tilt of the nozzle 44a using the tilt adjusting screw 422. In addition, it is possible to adjust the tangential tilt of the nozzle 44a by directly pushing the nozzle 44a with a hand, for example. It is also possible to measure the degree of the radial tilt of the nozzle 44a (that is, a distance from the inner wall of the reaction tube 10) by placing a spirit level on the nozzle 44a, using a jig, hanging a weight from the front end (tip) of the nozzle 44a, or using a three-dimensional shape measurer (which is a measuring structure).

### Configuration Example of Convolutional Neural Network CNN

Subsequently, an exemplary configuration of the convolutional neural network (CNN) will be described with reference to FIG. 8. FIG. 8 is a diagram schematically illustrating an exemplary flow of data when training an inference device (discriminator), and is related to training the inference device (discriminator) for an unencrypted image.

In FIG. 8, a pre-stage layer 540 is constituted by an input layer 541, a convolutional layer 542 and a pooling layer 543. For example, the convolutional layer 542 and the pooling layer 543 may be constituted by a plurality of layers.

A post-stage layer 550 is constituted by fully connected layers 551 and 552 and an output layer 553. Each of the fully connected layers 551 and 552 may be constituted by a single layer or three or more layers. In the training using unencrypted image data 530 in FIG. 8, parameter values and a layer structure of the post-stage layer 550 are configured to remain unchanged.

A training data generator (which is a training data generating structure) inputs the unencrypted image data 530 corresponding to labeled data (also referred to as a “teacher data”) T (532) (which is an image for the labeled data) to a training structure.

The unencrypted image data 530 is input to the inference device for the unencrypted image, which is a training target constituted by the pre-stage layer 540 and the post-stage layer 550.

An inference result value Y (531) output by the inference device for the unencrypted image and the labeled data T (532) are input to an error function 534 to obtain an error L (533). The error L (533) is fed back (535) to the pre-stage layer 540 of the inference device for the unencrypted image using the error backpropagation method, and the parameter values of each layer are adjusted for each epoch, from the first layer (fully connected layer) 551 of the post-stage layer 550 to the input layer 541, so as to reduce a value of the error L (533).

By using the flow of the machine learning shown in FIG. 5 and the convolutional neural network shown in FIG. 8 as described above, a trained model or a method of generating the image for the labeled data can be constructed as follows.

The trained model is capable of outputting at least one among the presence or absence of the abnormality and the degree of the abnormality in the substrate processing apparatus 1 from the images of the inside of the process vessel 17 of the substrate processing apparatus 1.

The parameters of the trained model are trained using the training data that associates the image information on the inside of the process vessel 17 (wherein the image information is obtained by the cameras 22 and 23 located outside the process vessel 17) in a state where one end (lower end) of the process vessel 17 is open and a part or the entirety of the boat 15 is unloaded from the process vessel 17, with the label information indicating the presence or absence and/or the degree of the abnormality in the substrate processing apparatus 1. The computer (that is, the controller 431 serving as the determination processor) is configured to perform: accommodating the wafers (substrates) 6 supported by the boat 15 into the process vessel 17 of a cylindrical shape and collectively processing (or batch-processing) the wafers (substrates) 6 supported by the boat 15; moving the boat 15 in the tube axis direction (axial direction) of the process vessel 17 by the mover (that is, the boat elevator 18); accepting, as an input, the image information on the inside of the process vessel 17 obtained by the cameras 22 and 23; executing calculations on the image information based on the parameters; and outputting an estimated result of the presence or absence and/or the degree of the abnormality in the substrate processing apparatus 1.

In addition, the method of generating the image for the labeled data is a method of generating images for training the discriminator (inference device) configured to estimate at least one among the presence or absence of the abnormality and the degree of the abnormality in the substrate processing apparatus 1 when the image of the inside of the process vessel 17 is input in a case where the wafers (substrates) 6 supported by the boat 15 are accommodated in the process vessel 17 of a cylindrical shape and collectively processed, and then the boat 15 is moved in the tube axis direction (axial direction) of the process vessel 17 by the mover (that is, the boat elevator 18).

For example, the method of generating the image for the labeled data includes: a step of capturing the images of the inside of the process vessel 17 by using the cameras 22 and 23 located outside the process vessel 17 in a state where one end (lower end) of the process vessel 17 is open and a part or the entirety of the boat 15 capable of being moved in the tube axis direction (axial direction) of the process vessel 17 by the mover (that is, the boat elevator 18) is unloaded from the process vessel 17; and a step of generating the image for the labeled data corresponding to the captured images (that is, the images captured by using the cameras 22 and 23) by performing at least one among: an image processing of simulation on the captured images to generate a simulated image of the same object captured under different conditions; and another image processing of combining a plurality of images of the same object captured under different conditions.

### First Modified Example

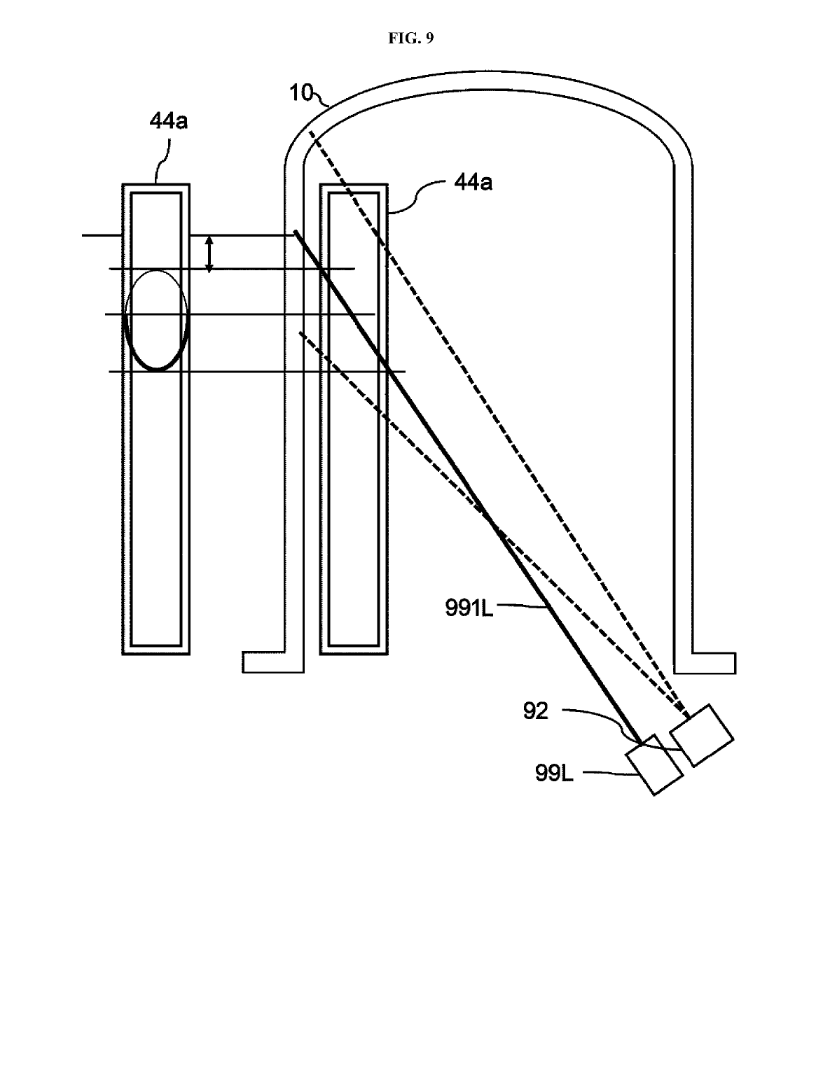

FIG. 9 is a diagram schematically illustrating an arrangement of an imaging system according to a first modified example of the present disclosure.

A scattered light from a surface of a transparent structure such as the nozzle 44a may be weak, and simply capturing the image with the cameras 22 and 23 may result in an insufficient S/N ratio (signal-to-noise ratio). Thus, a light-section method may be used. According to the light-section method, a laser light of a strip shape is irradiated onto a surface of a target object (in the present modified example, the nozzle 44a or the temperature detector 216) and diffused and reflected. Then, the reflected light is received and imaged by an imaging element or a camera, and changes in a height, a shape and a position of a cross-section of the target object are acquired as profile data.

In other words, the nozzle 44a and a part of the process vessel 17 adjacent to the nozzle 44a are irradiated with a light beam 991L from a line laser 99L, which is linearly deflected in an irradiation direction. Then, an image of a scattered reflection of the light beam 991L from surfaces of the nozzle 44a and the process vessel 17 is captured by using a camera 92. Thereby, the controller 431 serving as the determination processor can acquire the profile data of changes in a height, a shape and a position of a cross-section of the nozzle 44a from the images captured by the camera 92. According to the present modified example, it is possible to obtain substantially the same effects as in the embodiments mentioned above.

### Second Modified Example

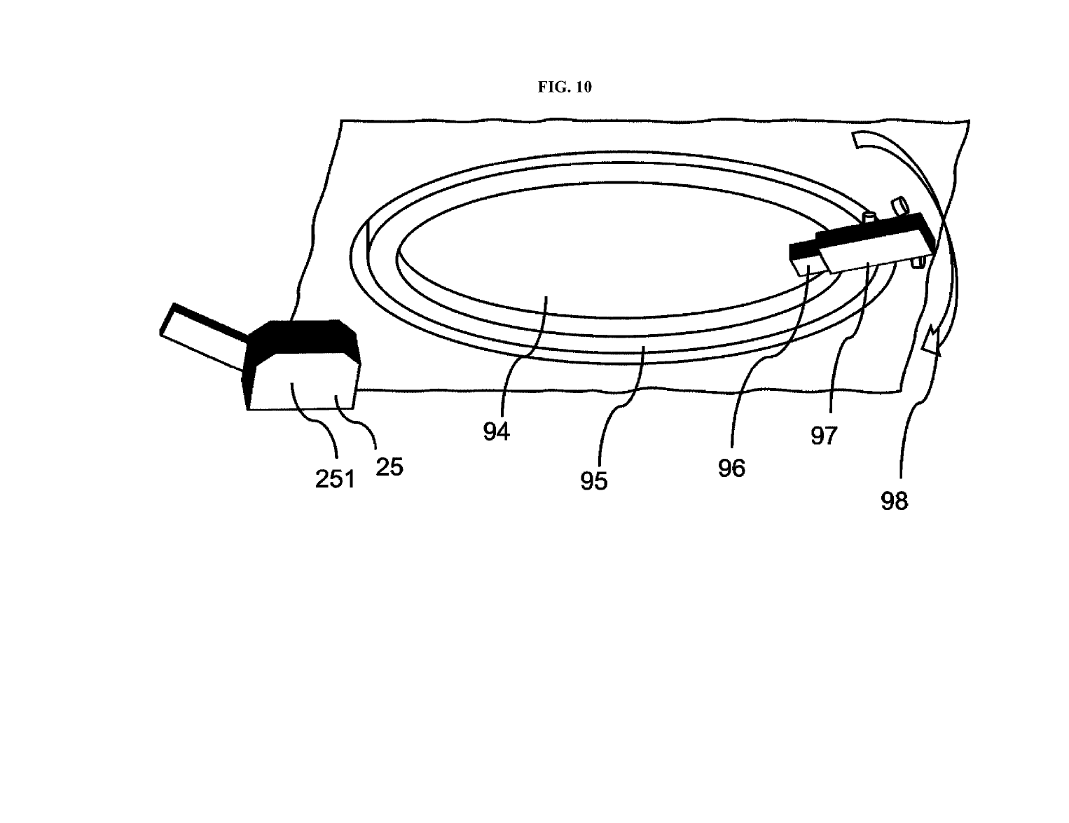

FIG. 10 is a diagram schematically illustrating an arrangement of an imaging system according to a second modified example of the present disclosure.

The second modified example is a configuration example in which a self-propelled camera is provided. FIG. 10 corresponds to a view of a ceiling side of the sub-housing 4 (that is, a ceiling side of the transfer chamber 12) when the process vessel 17 is viewed from the boat 15 in FIG. 2, and shows an opening 94 at one end (lower end) of the process vessel 17. In the present modified example, a shutter arm 251 (to which the shutter 20 is attached) is connected to the shutter driver 25.

A circular guide 95 is provided. The circular guide 95 is arranged in an arc shape along an outer periphery of the opening 94 at one end (lower end) of the process vessel 17. A camera holder 97 is provided to move a camera 96 along the circular guide 95 while maintaining a constant relationship between an optical axis of the camera 96 and the tube axis of the process vessel 17. For example, the camera holder 97 may be configured as a self-propelled robot. As a result, for example, the camera 96 can be moved along the circular guide 95 as indicated by an arrow 98. Thereby, the camera 96 is configured to be capable of capturing the images of the inside of the process vessel 17 from below along an entire inner periphery of the process vessel 17. As a result, the camera 96 can capture the images of the plurality of gas nozzles (such as the gas nozzle 44a and the like) provided inside the process vessel 17 at each corresponding angle of view.

According to the present modified example, a configuration in which the circular guide 95 is arranged along the outer periphery of the opening 94 is described. However, the present modified example is not limited thereto. For example, the circular guide 95 may be arranged in an arc shape along an outer periphery of the seal cap 19 serving as a lid configured to close the opening 94 of the process vessel 17 when the boat 15 is accommodated in the process vessel 17. With such a configuration, the camera 96 can also capture the images of the plurality of gas nozzles (such as the gas nozzle 44a and the like) provided inside the process vessel 17 at each corresponding angle of view. According to the present modified example, it is also possible to obtain substantially the same effects as in the embodiments mentioned above.

### Third Modified Example

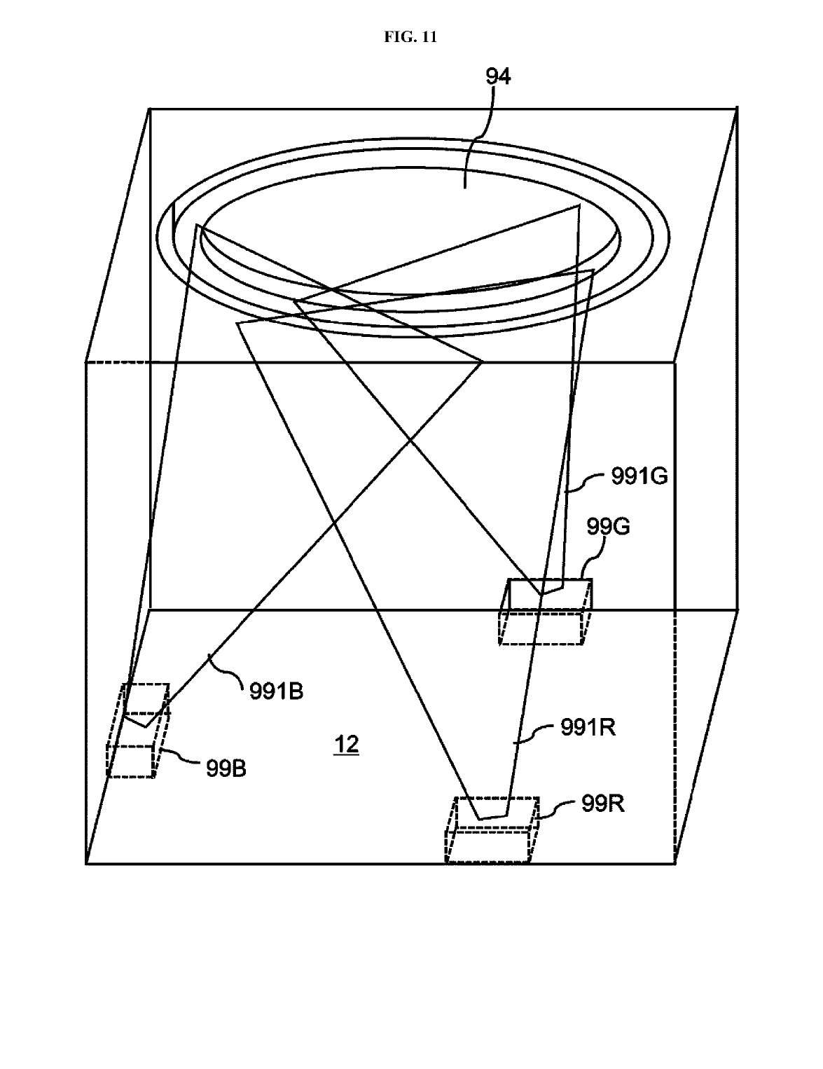

FIG. 11 is a diagram schematically illustrating an arrangement of an imaging system according to a third modified example of the present disclosure.

According to the present modified example, a light source 99R corresponding to red color 991R, a light source 99G corresponding to green color 991G and a light source 99B corresponding to blue color 991B are installed at a bottom of the transfer chamber 12, each spaced 120 degrees apart from one another with respect to the tube axis of the process vessel 17. For example, the light sources 99R, 99G and 99B can be turned on simultaneously such that an RGB camera can image the inside of the process chamber 17. According to the present modified example, the RGB camera is used to capture the light of red, green and blue wavelengths (RGB) and display a vivid color image. For example, the RGB camera may use a visible light with a wavelength between 400 nm and 700 nm. In addition, each of the cameras 22 and 23 in FIG. 2 and/or the camera 96 in the second modified example may be configured as the RGB camera.

According to the present modified example, it is also possible to obtain substantially the same effects as in the embodiments mentioned above. In addition, possible to obtain substantially the same effects as combining the images created under different lighting conditions.

For example, the light sources 99R, 99G and 99B may be turned on in a time-division manner, and images of the corresponding color channels may be acquired while the light sources are turned on, and then the color channels may be combined.

### Fourth Modified Example

The following configuration examples can be implemented by configuring the camera 22, 23 or 96 to capture an image of the boat 15 unloaded from the process furnace 16 or an image of the wafer (substrate) 6 inside the boat 15. In addition, a microcrack can sometimes be observed in the quartz structure (such as the nozzle 44a and the columns 26b of the boat 15) before the quartz structure is broken. When the microcrack can be identified from the images captured by the camera 22, 23 or 96, it is possible to predict a lifespan of the nozzle 44a or the columns 26b of the boat 15.

### First Configuration Example

The cameras 22, 23 and 96 are configured to capture images containing information on at least one among a color, a transparency and a contamination of the inner wall of the process vessel 17. The controller 431 serving as an AI determination processor can then predict a generation timing of particles that will obstruct an operation of the substrate processing apparatus 1, based on a machine learning model created in advance using a set of data containing (or including) the images (which is captured) and an index indicating an amount of the particles.

### Second Configuration Example

The cameras 22, 23 and 96 are configured to capture images of at least one among the process vessel 17, the boat 15 and the wafer (substrate) 6 before and after a predetermined process using the process vessel 17. In the present configuration example, for example, the term “predetermined process” may include the substrate processing such as the film forming process, as well as a cleaning process and a conditioning process for the process vessel 17. Based on a machine learning model created in advance using a set of data containing a first image obtained before the predetermined process, a second image obtained after the predetermined process and an index indicating a quality or characteristics of the predetermined process, the controller 431 serving as the AI determination processor can then estimate the quality or the characteristics of the predetermined process or the lifespan of the columns 26b of the boat 15 from the first and second images captured. In addition, it is possible to detect the abnormality in the substrate (such as warping and falling) from such camera images.

### Third Configuration Example

The cameras 22, 23 and 96 are configured to capture multispectral (RGB color) images of at least one among the process vessel 17 and the nozzle 44a. The controller 431 serving as the AI determination processor can then determine the lifespan of the nozzle 44a and the abnormality related to the flow of the gas (such as the process gas and a cleaning gas) from the colors of the nozzle 44a or the colors of the inside of the process furnace 16.

### Fourth Configuration Example

The cameras 22, 23 and 96 are configured to capture images of the plurality of wafers (substrates) 6 before and after the predetermined process using the process vessel 17. In the present configuration example, for example, the term “predetermined process” may include the substrate processing such as the film forming process, as well as the cleaning process and the conditioning process for the process vessel 17. Based on a machine learning model created in advance using a set of data containing a first image obtained before the predetermined process, a second image obtained after the predetermined process and an index indicating the state of the nozzle 44a or the process vessel 17, the controller 431 serving as the AI determination processor can then estimate the state of the nozzle 44a or the process vessel 17 from the first and second images captured. According to the present configuration example, the state of the nozzle 44a or the process vessel 17 may include an installation height of the nozzle 44a, a misalignment of the nozzle 44a, a contamination of the nozzle 44a, a presence or absence of the microcrack in the nozzle 44a, a contamination of the process vessel 17 and the like.

According to the present embodiments, it is possible to obtain one or more of the following effects. (a) Since the tilt of the nozzle 44a or the temperature detector 216 can be determined, it is possible to prevent the damage to the quartz structure due to the contact between the nozzle 44a (or the temperature detector 216) and the boat 15. It is also possible to reduce the downtime of the substrate processing apparatus 1. (b) By imaging the wafers (substrates) 6 stacked on the boat 15 with the cameras 22 and 23, it is possible to detect the abnormality in the wafers (substrates) 6 (such as the warping of the wafers 6 and the falling of the wafers 6) from the images captured by the cameras 22 and 23. (c) It is possible to predict the lifespan of the quartz structure such as the nozzle 44a, the columns 26b of the boat 15 and the temperature detector 216. (d) It is possible to evaluate and predict flow patterns of the process gas and the cleaning gas (CLN gas), a suitability of process conditions and process variations between wafers (substrates).

In addition, the technique of the present disclosure is not limited to the embodiments described above, and the technique of the present disclosure may be applied to various modified examples of the embodiments described above. For example, the embodiments described above are described in detail in order to explain the technique of the present disclosure in an easy-to-understand manner. That is, the technique of the present disclosure is not limited to those including an entirety of configurations of the embodiments described above. For example, the embodiments and the modified examples mentioned above may be appropriately combined. The process procedures and the process conditions of each combination thereof may be substantially the same as those of the embodiments or the modified examples mentioned above.

For example, the embodiments mentioned above are described by way of an example in which a batch type substrate processing apparatus capable of simultaneously processing a plurality of substrates is used. However, the technique of the present disclosure is not limited thereto. For example, the technique of the present disclosure may be preferably applied when a single wafer type substrate processing apparatus capable of processing one or several substrates at a time is used. For example, the embodiments mentioned above are described by way of an example in which the substrate processing apparatus 1 including a hot wall type process furnace is used. However, the technique of the present disclosure is not limited thereto. For example, the technique of the present disclosure may be preferably applied when a substrate processing apparatus including a cold wall type process furnace is used.

As described above, according to some embodiments of the present disclosure, it is possible to prevent the damage to the quartz structure inside the process vessel.

What is claimed is:

1. A substrate processing apparatus comprising:
a process vessel of a tubular shape in which a plurality of substrates supported by a boat are accommodated and collectively processed;
a mover configured to move the boat in a tube axis direction of the process vessel;
a camera located outside the process vessel and configured to be capable of imaging an inside of the process vessel in a state where one end of the process vessel is open and a part or an entirety of the boat is unloaded from the process vessel; and
a determination processor configured to be capable of causing the camera to capture an image of the inside of the process vessel in a state where the boat unloaded by the mover is located at the one end of the process vessel, and further configured to be capable of determining at least one among a presence or absence of an abnormality and a degree of the abnormality from the image captured by the camera.

2. The substrate processing apparatus of claim 1, wherein the determination processor is further configured to be capable of determining at least one among the presence or absence of the abnormality and the degree of the abnormality, based on a machine learning model created in advance using an image captured by another camera when another substrate processing apparatus is normal, wherein the another substrate processing apparatus is provided with another process vessel and the another camera in substantially same layout as the substrate processing apparatus provided with the process vessel and the camera.

3. The substrate processing apparatus of claim 1, further comprising
a tubular structure located at a predetermined position inside the process vessel,
wherein the camera is further configured to be capable of, when the boat accommodates the plurality of substrates processed in the process vessel and unloaded from the process vessel, imaging the inside of the process vessel and the tubular structure through a gap between the boat and an opening at the one end of the process vessel while a heater configured to heat the process vessel is maintained in a powered state.

4. The substrate processing apparatus of claim 1, further comprising
a gas nozzle located at a predetermined position inside the process vessel,
wherein the determination processor is further configured to be capable of determining a presence or absence or a degree of an abnormality in a distance between an inner wall of the process vessel and the gas nozzle, or in a parallelism between a tube axis of the process vessel and the gas nozzle.

5. The substrate processing apparatus of claim 1, further comprising
a shutter configured to close the one end of the process vessel when the boat is being unloaded from the process vessel,
wherein the shutter is provided with one or more cameras or one or more mirrors attached to an edge thereof, and
wherein the one or more cameras are configured to be capable of imaging the inside of the process vessel during an opening and closing operation of the shutter.

6. The substrate processing apparatus of claim 2, further comprising:
a guide arranged in an arc shape along an outer periphery of an opening at the one end of the process vessel or along an outer periphery of a lid configured to close the opening of the process vessel when the boat is accommodated in the process vessel; and
a camera holder provided to move the camera along the guide while maintaining a constant relationship between an optical axis of the camera and a tube axis of the process vessel,
wherein the camera is further configured to be capable of imaging a plurality of gas nozzles at corresponding angles of view.

7. The substrate processing apparatus of claim 4, wherein the boat comprises a plate provided with a transparent portion or an opening located substantially perpendicular to the tube axis of the process vessel and to which a plurality of substrate support columns are connected, wherein the transparent portion or the opening of the plate is provided on a portion closest to the process vessel when the boat is unloaded from the process vessel, and
wherein the camera is located at a position that enables the camera to image the gas nozzle through the transparent portion or the opening of the plate.

8. The substrate processing apparatus of claim 4, further comprising
a mirror provided at a location where a target location of image capture of the gas nozzle is visible through a gap between an opening of the process vessel and the boat when the boat is unloaded from the process vessel such that a light from the target location of image capture is capable of being directed to the camera.

9. The substrate processing apparatus of claim 4, wherein the gas nozzle and a part of the process vessel adjacent to the gas nozzle are irradiated with a light beam from a line laser which is linearly deflected in an irradiation direction, and
wherein the camera is further configured to be capable of capturing an image of a scattered reflection of the light beam from surfaces of the gas nozzle and the process vessel.

10. The substrate processing apparatus of claim 1, wherein the camera is further configured to be capable of capturing an image containing information on at least one among a color, a transparency and a contamination of an inner wall of the process vessel, and
wherein the determination processor is further configured to be capable of predicting a generation timing of particles obstructing an operation of the substrate processing apparatus, based on a machine learning model created in advance using a set of data containing the image containing the information and an index indicating an amount of the particles.

11. The substrate processing apparatus of claim 1, wherein the camera is further configured to be capable of capturing images of at least one among the process vessel, the boat and the plurality of substrates before and after a predetermined process using the process vessel, and
wherein the determination processor is further configured to be capable of estimating a quality or characteristics of the predetermined process from the images captured by the camera, based on a machine learning model created in advance using a set of data containing a first image obtained before the predetermined process, a second image obtained after the predetermined process and an index indicating the quality or the characteristics of the predetermined process.

12. The substrate processing apparatus of claim 4, wherein the camera is further configured to be capable of capturing multispectral images of at least one among the process vessel and the gas nozzle, and
wherein the determination processor is further configured to be capable of determining an abnormality related to a flow of a gas from colors of the gas nozzle or colors of the inside of the process vessel.

13. The substrate processing apparatus of claim 4, wherein the camera is further configured to be capable of capturing images of the plurality of substrates before and after a predetermined process using the process vessel, and
wherein the determination processor is further configured to be capable of estimating a state of the nozzle or a state of the process vessel from the images of the plurality of substrates, based on a machine learning model created in advance using a set of data containing a first image obtained before the predetermined process, a second image obtained after the predetermined process and an index indicating the state of the nozzle or the state of the process vessel.

14. The substrate processing apparatus of claim 1, further comprising:
a memory capable of storing a trained model configured to output at least one among the presence or absence and the degree of the abnormality in the substrate processing apparatus from the image of the inside of the process vessel of the substrate processing apparatus captured by the camera, wherein parameters of the trained model are trained using training data that associates image information on the inside of the process vessel captured by the camera located outside the process vessel in a state where the one end of the process vessel is open and a part or the entirety of the boat is unloaded from the process vessel, with label information indicating at least one among the presence or absence and the degree of the abnormality in the substrate processing apparatus; and
a computer configured to be capable of:
accommodating the plurality of substrates supported by the boat into the process vessel of the tubular shape and collectively processing the plurality of substrates supported by the boat;
moving the boat in the tube axis direction of the process vessel by the mover;
accepting, as an input, the image information on the inside of the process vessel captured by the camera;
executing calculations of the image information based on the parameters; and
outputting an estimated result of at least one among the presence or absence and the degree of the abnormality in the substrate processing apparatus.

15. A substrate processing method comprising:
(a) accommodating a plurality of substrates supported by a boat into a process vessel of a tubular shape and collectively processing the plurality of substrates supported by the boat;
(b) moving the boat in a tube axis direction of the process vessel by a mover after (a) and unloading the boat from the process vessel;
(c) imaging an inside of the process vessel by using a camera located outside the process vessel in a state where one end of the process vessel is open; and
(d) determining at least one among a presence or absence and a degree of an abnormality from an image captured by using the camera.

16. The substrate processing method of claim 15, further comprising
(e) generating an image for labeled data corresponding to the image captured by using the camera by performing at least one of: an image processing of simulation on the captured image to generate a simulated image of same object captured under different conditions; or another image processing of combining a plurality of images of the same object captured under different conditions.

17. A method of manufacturing a semiconductor device, comprising
the method of claim 15.

18. A non-transitory computer-readable recording medium storing a program that causes a substrate processing apparatus, by a computer, to perform:
(a) accommodating a plurality of substrates supported by a boat into a process vessel of a tubular shape and collectively processing the plurality of substrates supported by the boat;
(b) moving the boat in a tube axis direction of the process vessel by a mover after (a) and unloading the boat from the process vessel;
(c) imaging an inside of the process vessel by using a camera located outside the process vessel in a state where one end of the process vessel is open; and
(d) determining at least one among a presence or absence and a degree of an abnormality from an image captured by using the camera.
